(19) United States
(12) Patent Application Publication
(10) Pub. No.: US 2017/0077445 A1
(43) Pub. Date: Mar. 16, 2017

(54) DISPLAY APPARATUS

(71) Applicant: SAMSUNG DISPLAY CO., LTD., Yongin-si (KR)

(72) Inventor: Jiwon HAN, Yongin-si (KR)

(21) Appl. No.: 15/145,012

(22) Filed: May 3, 2016

(30) Foreign Application Priority Data
Sep. 15, 2015 (KR) 10-2015-0130614

(51) Int. Cl. H01L 51/52; G02F 1/1335; G02F 1/1333; G06F 3/041; G02F 1/1341

(52) U.S. Cl. CPC H01L 51/5253; G06F 3/0412; G02F 1/1341; G02F 1/13338; G02F 1/133528

(57) ABSTRACT

A display apparatus, including a display including a display element; an encapsulation layer on the display, the encapsulation layer including an outmost inorganic film; and a self-assembled monolayer on the encapsulation layer, self-assembled monolayer including a head portion, a chain portion connected to the head portion, and an end portion connected to the chain portion.

### CROSS-REFERENCE TO RELATED APPLICATION

Korean Patent Application No. 10-2015-0130614, filed on Sep. 15, 2015, in the Korean Intellectual Property Office, and entitled: “Display Apparatus,” is incorporated by reference herein in its entirety.

### BACKGROUND

1. Field

One or more exemplary embodiments relate to a display apparatus.

2. Description of the Related Art

A display apparatus may have diverse purposes. For example, a display apparatus may become thin and lightweight, and the trend to use the display apparatus may become broad.

### SUMMARY

Embodiments may be realized by providing a display apparatus, including a display including a display element to realize a visible light beam; an encapsulation layer on the display, the encapsulation layer including an outmost inorganic film; and a self-assembled monolayer on the encapsulation layer, self-assembled monolayer including a head portion, a chain portion connected to the head portion, and an end portion connected to the chain portion.

The head portion of the self-assembled monolayer may be connected to the outmost inorganic film of the encapsulation layer.

The head portion of the self-assembled monolayer may include silicon.

The head portion of the self-assembled monolayer may be connected to the outmost inorganic film of the encapsulation layer through covalent bonds.

The chain portion of the self-assembled monolayer may include an alkyl chain.

The end portion of the self-assembled monolayer may include a hydroxyl group, a methyl group, an amino group, or a phosphate group.

The encapsulation layer may include one or more organic films and one or more inorganic films between the outmost inorganic film and the display.

The display apparatus may further include an adhesive layer on a first surface of the self-assembled monolayer opposite to a second surface of the self-assembled monolayer facing the encapsulation layer, among surfaces of the self-assembled monolayer.

The adhesive layer may include silicon.

The adhesive layer may include a pressure sensitive adhesive.

The display apparatus may further include a polarization layer on a first surface of the adhesive layer opposite to a second surface of the adhesive layer facing the self-assembling monolayer, among surfaces of the adhesive layer.

The display apparatus may further include a touch panel on a first surface of the adhesive layer opposite to a second surface of the adhesive layer facing the self-assembled monolayer, among surfaces of the adhesive layer, and detecting a user touch on the touch panel.

The display apparatus may further include a cover member on a first surface of the adhesive layer opposite to a second surface of the adhesive layer facing the self-assembled monolayer, among surfaces of the adhesive layer.

The display apparatus may further include a polarization layer, a touch panel, and a cover member sequentially on a first surface of the adhesive layer opposite to a second surface of the adhesive layer facing the self-assembled monolayer, among surfaces of the adhesive layer.

The display element may include a first electrode, a second electrode, and an intermediate layer; and the intermediate layer may include at least one organic light-emitting device, the intermediate layer being between the first electrode and the second electrode.

### BRIEF DESCRIPTION OF THE DRAWINGS

Features will become apparent to those of skill in the art by describing in detail exemplary embodiments with reference to the attached drawings in which:

FIG. 1 illustrates a schematic cross-sectional view of a display apparatus according to one exemplary embodiment;

FIG. 2 illustrates an enlarged view of a region A of FIG. 1;

FIG. 3 illustrates an enlarged view of a region B of FIG. 1;

FIG. 4 illustrates an enlarged view of a region C of FIG. 1;

FIG. 5 illustrates a view of a modification of the region C of FIG. 4;

FIG. 6 illustrates a schematic cross-sectional view of a display apparatus according to an exemplary embodiment;

FIG. 7A illustrates an enlarged view of a region A of FIG. 6;

FIG. 7B illustrates a view of a modification of the region A of FIG. 7A;

FIG. 7C illustrates a view of another modification of the region A of FIG. 7A;

FIG. 8 illustrates a schematic cross-sectional view of a display apparatus according to an exemplary embodiment;

FIG. 9 illustrates a schematic cross-sectional view of a display apparatus according to an exemplary embodiment;

FIG. 10 illustrates a schematic cross-sectional view of a display apparatus according to an exemplary embodiment;

FIG. 11 illustrates a schematic cross-sectional view of a display apparatus according to an exemplary embodiment; and

FIG. 12 illustrates a schematic cross-sectional view of a display apparatus according to one exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the accompanying drawings, like reference numerals refer to like elements throughout. It will be understood that although the terms “first”, “second”, etc. may be used herein to describe various components, these components should not be limited by these terms. These components are only used to distinguish one component from another component.

As used herein, the singular forms “a,” “an”, and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “formed on,” another layer, region, or component, it can be directly or indirectly formed on the other layer, region, or component. That is, for example, intervening layers, regions, or components may be present. In addition, it will also be understood that when a layer is referred to as being “between” two layers, it can be the only layer between the two layers, or one or more intervening layers may also be present.

Sizes of elements in the drawings may be exaggerated for convenience of explanation. In other words, since sizes and thicknesses of components in the drawings are arbitrarily illustrated for convenience of explanation, the following embodiments are not limited thereto.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

In exemplary embodiments, when a film, layer, region and component are connected to each other, “connection” may include a direct connection between the film, layer, region, and component and also include an indirectly connection between the film, layer, region, and component through another the film, layer, region, or component. For example, when the present disclosure states that a film, layer, region, and component is electrically connected to each other, the connection may include not only a direct connection between the film, layer, region, and component but also an indirect connection between the film, layer, region, and component though another film, layer, region, or component.

As used herein, the term “and/or” includes any and all combinations of one or more of the associated listed items. Expressions such as “at least one of,” when preceding a list of elements, modify the entire list of elements and do not modify the individual elements of the list.

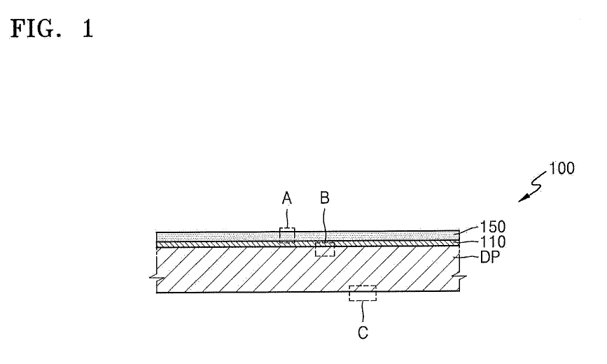

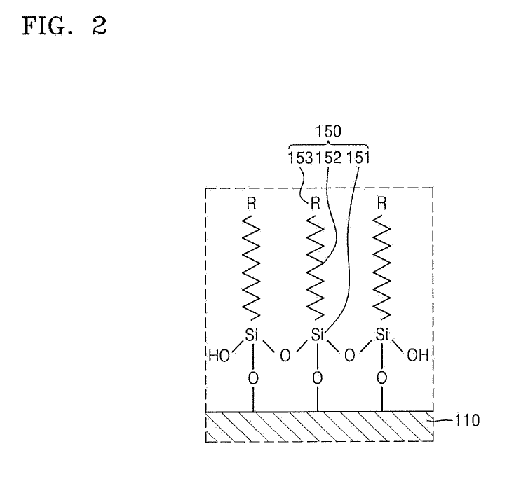

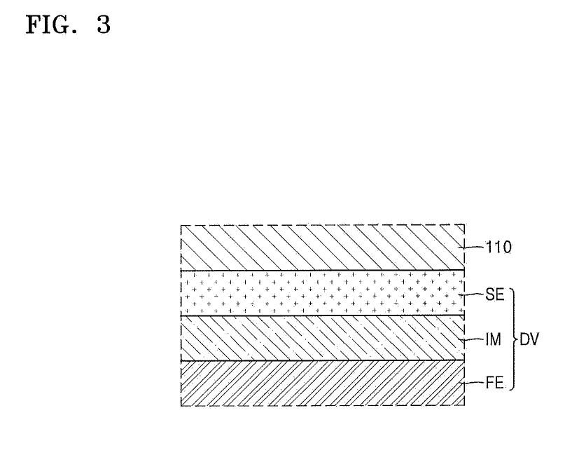

FIG. 1 illustrates a schematic cross-sectional view of a display apparatus 100 according to one exemplary embodiment, FIG. 2 illustrates an enlarged view of a region A of FIG. 1, and FIG. 3 illustrates an enlarged view of a region B of FIG. 1.

Referring to FIGS. 1 to 3, the display apparatus 100 may include a display unit DP, an encapsulation unit 110, and a self-assembled monolayer (SAM) 150.

The display unit DP may include a display element DV to realize at least a visible light beam. The display element DV may include various kinds of display elements. The display element DV is described, for example, as an organic light-emitting device in the present exemplary embodiment. The display element DV may include other various kinds of display elements.

Details of the display element DV will be explained with reference to FIG. 3 later.

The encapsulation unit 110 may be formed on the display unit DP. The encapsulation unit 110 may protect the display unit DP and also protect the display element DV.

The encapsulation unit 110 may include at least an inorganic film as an outmost layer of the encapsulation unit 110.

The encapsulation unit 110 may be an inorganic film according to one exemplary embodiment.

The encapsulation unit 110 may be disposed on an upper surface of the display unit DP, and may be disposed on a side surface of the display unit DP according to one exemplary embodiment.

The encapsulation unit 110 may cover the display element DV according to one exemplary embodiment.

The SAM 150 may be formed on the encapsulation unit 110.

According to an exemplary embodiment, the encapsulation unit 110 may include an outmost inorganic film, and the SAM 150 may contact the outmost inorganic film of the encapsulation unit 110. The outmost inorganic film of the encapsulation unit 110 may include various materials, for example, oxide or nitride.

According to an exemplary embodiment, the outmost inorganic film of the encapsulation unit 110 may include silicon oxide or silicon nitride.

The SAM 150 may include a head portion 151, a chain portion 152, and an end portion 153.

The head portion 151 may be formed on the encapsulation unit 110. When the encapsulation unit 110 includes an outmost inorganic film, the head portion 151 may contact the outmost inorganic film of the encapsulation unit 110.

Through the above-described structure, the SAM 150 may protect the encapsulation unit 110, as described above.

When the SAM 150 is formed on the outmost inorganic film of the encapsulation unit 110, crack generation and propagation, which may occur on a surface of the outmost inorganic film of the encapsulation unit 110, may be reduced.

The head portion 151 may include silicon. The head portion 151 may form covalent bonds with a surface of the encapsulation unit 110. For example, the silicon of the head portion 151 may be bonded to the surface of the encapsulation unit 110 through oxygen of the head portion 151. The surface of the encapsulation unit 110, for example, the surface of the outmost organic film of the encapsulation unit 110, may be effectively protected according to the bonding between the head portion 151 and the surface of the encapsulation unit 110.

The above-described bonding process may be performed by using various methods. For example, the bonding process may be performed according to a silane coupling reaction by using a material including silane.

As an example of a manufacturing method, the material including silane may be deposited on the encapsulation unit 110 according a vapor deposit method of forming the SAM 150.

The chain portion 152 may be connected to the head portion 151. For example, the chain portion 152 may include carbon. According to an exemplary embodiment, the chain portion 152 may include an alkyl chain.

The end portion 153 may be connected to the chain portion 152. For example, the chain portion 152 may be disposed between the head portion 151 and the end portion 153.

The end portion 153 may include various kinds of end groups R. For example, the end group R may include a hydroxyl group (—OH). When the end group R includes a hydroxyl group (—OH), the surface energy of the end portion 153 may be easily controlled to process a hydrophilic surface treatment. Through this process, after the SAM 150 is formed on the encapsulation unit 110, various layers may be formed thereon, and the encapsulation unit 110 may be easily and stably bonded to the various layers.

According to one exemplary embodiment, the end portion 153 may include various end groups R. The end portion 153 may include a methyl group (—CH₃), an amino group (—NH₂), or a phosphate group (—PO₃). According to selection of the various end groups R, the surface energy of the end portion 153 may be controlled to control adhesiveness of the SAM 150 such that various kinds of layers, which may be formed on the SAM 150, may be stably bonded to the SAM 150 and the encapsulation unit 110.

The display element DV of the display apparatus 100 according to the present embodiment may be an organic light-emitting device and may include a first electrode FE, a second electrode SE, and an intermediate layer IM, as illustrated in FIG. 3.

The intermediate layer IM may be disposed between the first electrode FE and the second electrode SE.

The first electrode FE may include various conductive materials. For example, the first electrode FE may include one or more transparent conductive oxide, such as indium tin oxide (ITO), indium zinc oxide (IZO), zinc oxide (ZnO), indium oxide (In₂O₃), indium gallium oxide (IGO), or aluminum zinc oxide (AZO). The first electrode FE may include a metal having high reflectivity, such as silver (Ag).

The intermediate layer IM may include an organic light-emitting layer, and the organic light-emitting layer may include a low molecule organic compound or a polymer organic compound. According to an exemplary embodiment, the intermediate layer IM may include the organic light-emitting layer and further include one or more of a hole injection layer, a hole transport layer, an electron transport layer, or an electron injection layer.

The second electrode SE may include various conductive materials. For example, the second electrode SE may include lithium (Li), calcium (Ca), lithium fluoride (LiF), aluminum (Al), magnesium (Mg), or silver (Ag), may include a single layer or multilayer including at least one of the above materials, or an alloy including at least two of the above materials.

The display element DV may further include a circuit unit, which may be connected to the first electrode FE or the second electrode SE, for example, one or more thin film transistors.

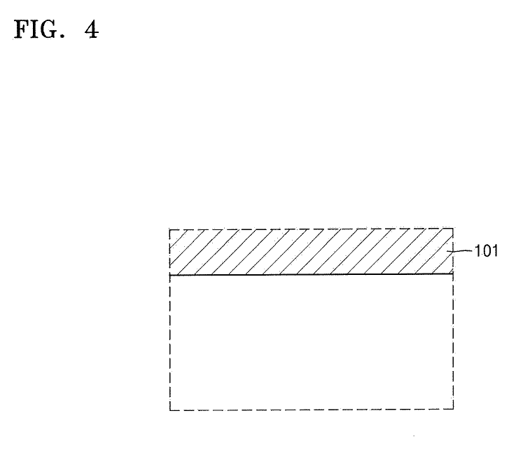

According to an embodiment, the display unit DP may further include a substrate 101, as illustrated in FIG. 4.

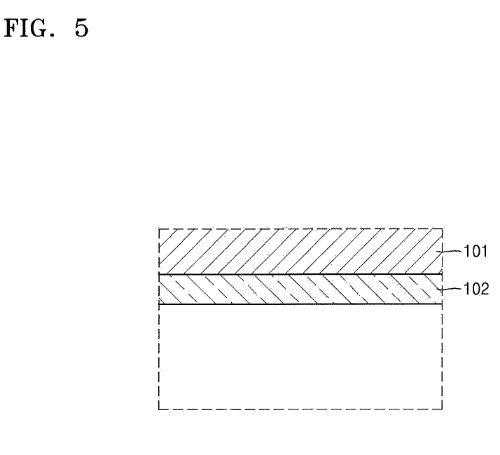

FIG. 4 illustrates an enlarged view of a region C of FIG. 1, and FIG. 5 illustrates a view of a modification of the region C of FIG. 4.

Referring to FIG. 4, the display unit DP may include the substrate 101, and the display element DV may be formed on the substrate 101.

The substrate 101 may include various materials. The substrate 101 may include glass, a metal, an organic compound, etc.

According to an exemplary embodiment, the substrate 101 may include a flexible material. For example, the substrate 101 may be flexible, bendable, foldable, or rollable.

According to an embodiment, the substrate 101 may include ultra-thin glass, metal or plastic. For example, when the substrate 101 includes plastic, the substrate 101 may include polyimide. In an embodiment, the substrate 101 may include various materials.

According to an embodiment, as illustrated in FIG. 5, a protection layer 102 may be disposed on a lower surface of the substrate 101, for example, on a first surface of the substrate 101 disposed opposite to a second surface of the substrate 101 facing the display element DV, among surfaces of the substrate 101. The protection layer 102 may include an organic compound or an inorganic compound and protect the substrate 101. According to an exemplary embodiment, the protection layer 102 may be a film.

The display apparatus 100 according to the present embodiment may include the encapsulation unit 110, which may be formed on the display unit DP, and the SAM 150, which may be formed on the encapsulation unit 110. The encapsulation unit 110 may be effectively protected by the SAM 150. For example, the SAM 150 may be formed on the surface of the outmost inorganic film of the encapsulation unit 110, and cracks may be prevented from occurring on the outmost inorganic film of the encapsulation unit 110, and the surface of the outmost inorganic film of the encapsulation unit 110 may be effectively protected.

The bonding between the encapsulation unit 110 and the SAM 150 may reduce the surface delamination of the encapsulation unit 110.

The end portion 153 of the SAM 150 may control the surface energy of the SAM 150 to improve a bonding force between the SAM 150 and a member that may be formed on an upper surface of the SAM 150.

For example, when the display apparatus 100 is flexible, bendable, or foldable, for example, the display unit DP may include the substrate 101, which may include a flexible material, and cracks or defects may occur in the outmost inorganic film of the encapsulation unit 110. The SAM 150 may reduce the cracks and defects or may restore the cracks and defects.

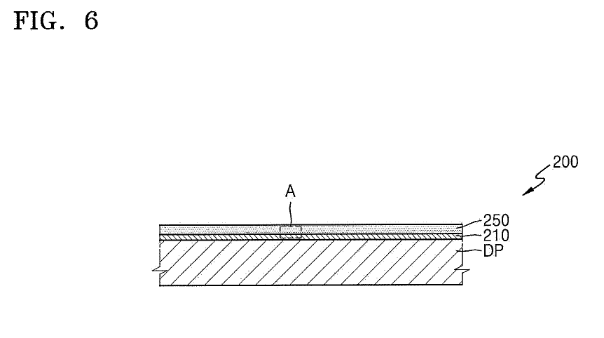

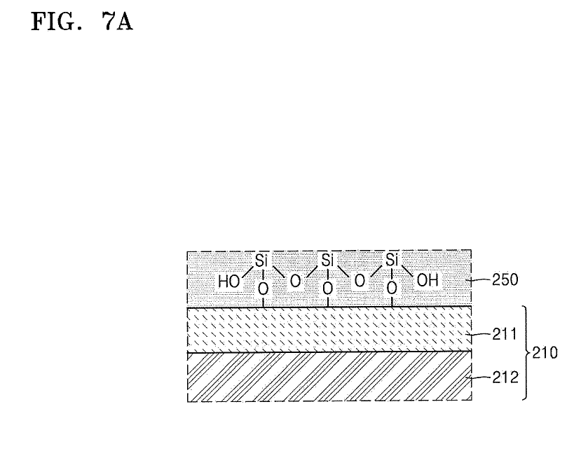

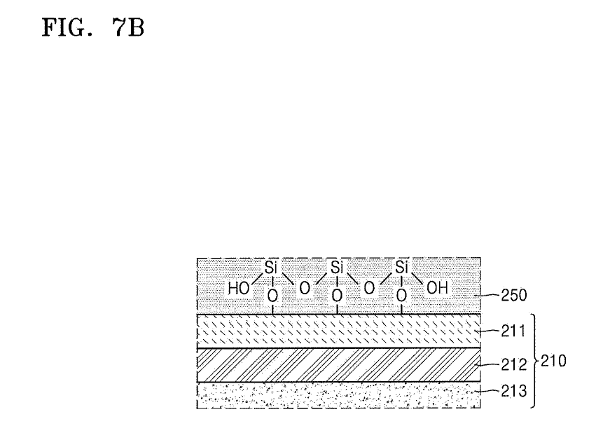

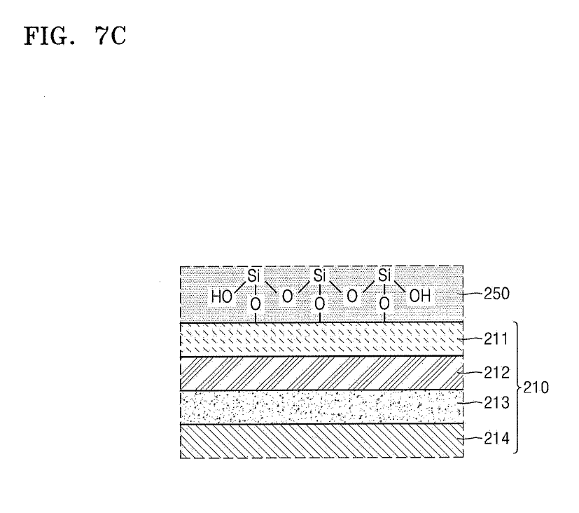

FIG. 6 illustrates a schematic cross-sectional view of a display apparatus 200 according to an exemplary embodiment, FIG. 7A illustrates an enlarged view of a region A of FIG. 6, FIG. 7B illustrates a view of a modification of the region A of FIG. 7A, and FIG. 7C illustrates a view of another modification of the region A of FIG. 7A.

Referring to FIG. 6, the display apparatus 200 according to the present embodiment may include a display unit DP, an encapsulation unit 210, and an SAM 250.

For convenience, different elements from the previously described embodiments will be explained.

The display unit DP may include a display element to realize at least a visible light beam. The display element may include various kinds of display elements. The display element may be the organic light-emitting device as described in the previously described embodiments. According to an exemplary embodiment, the display element may include a liquid crystal display element or other various kinds of display elements.

The encapsulation unit 210 may be formed on the display unit DP. The encapsulation unit 210 may protect the display unit DP and also may protect the display element.

The encapsulation unit 210 may include at least an inorganic film at an outmost area of the encapsulation unit 210.

As illustrated in FIG. 7A, the encapsulation unit 210 may include a first inorganic film 211, which may be disposed at the outmost area of the encapsulation unit 210, and a first organic film 212. The first inorganic film 211 may contact the SAM 250. The first inorganic film 211 may be formed on the first organic film 212.

According to an exemplary embodiment, as illustrated in FIG. 7B, the encapsulation unit 210 may include the first inorganic film 211, the first organic film 212, and a second inorganic film 213. The first inorganic film 211 may contact the SAM 250. The first inorganic film 211 may be formed on the first organic film 212. The first organic film 212 may be disposed between the first inorganic film 211 and the second inorganic film 213.

According to an exemplary embodiment, as illustrated in FIG. 7C, the encapsulation unit 210 may include the first inorganic film 211, the first organic film 212, the second inorganic film 213, and a second organic film 214. The first inorganic film 211 may contact the SAM 250. The first inorganic film 211 may be disposed on the first organic film 212. The first organic film 212 may be disposed between the first inorganic film 211 and the second inorganic film 213. The second inorganic film 213 may be disposed on the second in organic film 214.

The encapsulation unit 210 may have various shapes. One or more inorganic films or one or more organic films may be disposed below the first inorganic film 211.

The SAM 250 may be formed on the encapsulation unit 210.

The SAM 250 may be similar to or same as the previously described embodiments, and detail descriptions thereof will be omitted.

The display unit DP according to the present embodiment may further include a substrate, as in previously described embodiments.

The display apparatus 200 according to the present embodiment may include the encapsulation unit 210, which may be formed on the display unit DP, and the SAM 250, which may be formed on the encapsulation unit 210. The SAM 250 may effectively protect the encapsulation unit 210. For example, the SAM 250 may be formed on a surface of the outmost inorganic film of the encapsulation unit 210, and the cracks, which may occur in the outmost inorganic film, may be effectively prevented, and the surface of the outmost inorganic film may be effectively protected.

The encapsulation unit 210 may be bonded to the SAM 250 and may prevent the surface delamination of the encapsulation unit 210.

The end portion of the SAM 250 may control the surface energy of the SAM 250 to improve a bonding force between the SAM 250 and the member, which may be disposed on an upper surface of the SAM 250.

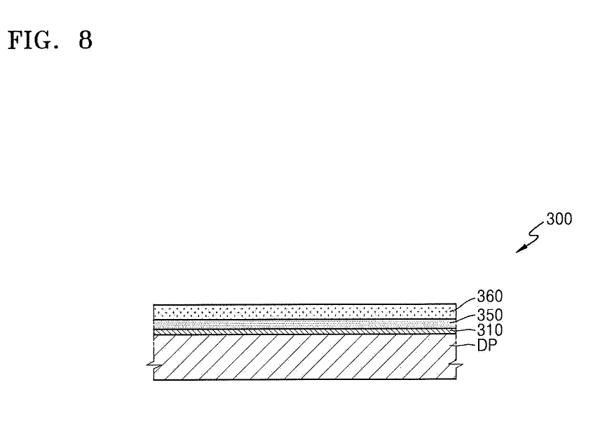

FIG. 8 illustrates a schematic cross-sectional view of a display apparatus 300 according to an exemplary embodiment.

Referring to FIG. 8, the display apparatus 300 according to the present embodiment may include a display unit DP, an encapsulation 310, an SAM 350, and an adhesive layer 360.

For convenience, different elements from the previously described embodiments will be explained.

The display unit DP may include a display element to realize at least a visible light beam. The display element may include various kinds of display elements. The display element may be the organic light-emitting device as described in the previously described embodiments. According to an exemplary embodiment, the display element may include a liquid crystal display element or other various kinds of display elements.

The encapsulation unit 310 may be formed on the display unit DP. The encapsulation unit 310 may protect the display unit SP and also protect the display element.

The encapsulation unit 310 may include at least an outmost inorganic film. The encapsulation unit 310 may selectively include a structure illustrated in FIG. 7A, FIG. 7B, or FIG. 7C, for example.

The SAM 350 may be formed on the encapsulation unit 310.

The SAM 350 may be substantially the same as the SAM 150 or 250, and detail descriptions thereof will be omitted.

The display unit DP according to the present embodiment may include a substrate as stated above.

The adhesive layer 360 may be formed above the SAM 350.

The adhesive layer 360 may be formed on the SAM 350 and may include various materials. For example, the adhesive layer 360 may include silicon.

The adhesive layer 360 including silicon may improve adhesive properties with the SAM 350, which may be formed by using silane.

According to an exemplary embodiment, the adhesive layer 360 may include a pressure sensitive adhesive (PSA).

In the display apparatus 300 according to the present embodiment, the encapsulation unit 310 may be formed on the display unit DP, and the SAM 350 may be formed on the encapsulation unit 310. The SAM 350 may effectively protect the encapsulation unit 310. For example, the SAM 350 may be formed on a surface of the outmost inorganic film of the encapsulation unit 310, cracks may be prevented from occurring in the inorganic film of the encapsulation unit 310, and the surface of the outmost inorganic film of the encapsulation unit 310 may be effectively protected.

The encapsulation unit 310 and the SAM 350 may be bonded to each other, and delamination phenomena of a surface of the encapsulation unit 310 may be reduced.

The end portion of the SAM 350 may control the surface energy of the SAM 350, and the adhesive properties between the SAM 350 and the adhesive layer 360, which may be formed on an upper surface of the SAM 350, may be improved.

The SAM 350 may reduce the delamination of the adhesive layer 360 from the surface of the encapsulation unit 310 and also reduce damage to the surface of the encapsulation unit 310 by the adhesive layer 360.

By using the above-described structure, other members may be stably arranged on an upper portion of the adhesive layer 360.

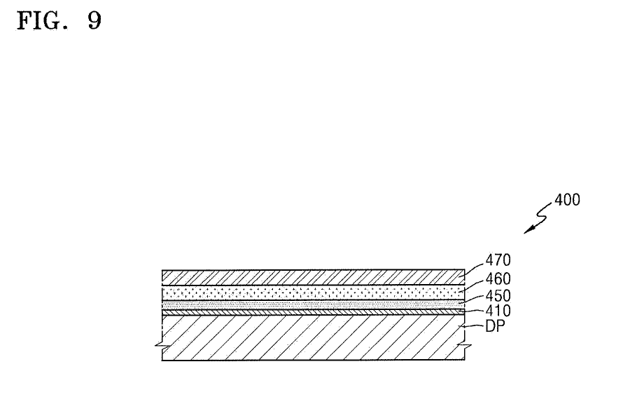

FIG. 9 illustrates a schematic cross-sectional view of a display apparatus 400 according to an exemplary embodiment.

Referring to FIG. 9, the display apparatus 400 according to the present embodiment may include a display unit DP, an encapsulation 410, an SAM 450, an adhesive layer 460, and a polarization layer 470.

For convenience, different elements from the previously described embodiments will be explained.

The display unit DP may include a display element to realize at least a visible light beam. The display element may include various kinds of display elements. The display element may be the organic light-emitting device as described in the previously described embodiments. According to an exemplary embodiment, the display element may include a liquid crystal display element or other various kinds of display elements.

The encapsulation unit 410 may be formed on the display unit DP. The encapsulation unit 410 may protect the display unit SP and also protect the display element.

The encapsulation unit 410 may include at least an outmost inorganic film. The encapsulation unit 410 may selectively include a structure illustrated in FIG. 7A, FIG. 7B, or FIG. 7C, for example.

The SAM 450 may be formed on the encapsulation unit 410.

The SAM 450 may be substantially the same as the SAM 150, 250, or 350, and detail descriptions thereof will be omitted.

The display unit DP according to the present embodiment may include a substrate as stated above.

The adhesive layer 460 may be formed above the SAM 450.

The adhesive layer 460 may be formed on the SAM 450 and may include various materials. For example, the adhesive layer 460 may include silicon.

The adhesive layer 460 including silicon may improve adhesive properties with the SAM 450, which may be formed by using silane.

According to an exemplary embodiment, the adhesive layer 460 may include a PSA.

The polarization layer 470 may be formed on the adhesive layer 460. For example, the adhesive layer 460 may be disposed between the polarization layer 470 and the SAM 450.

The polarization layer 470 may include at least one selected from various materials having a polarizing function and may improve a contrast of the display apparatus 400.

In the display apparatus 400 according to the present embodiment, the SAM 450 may effectively protect the encapsulation unit 410. For example, the SAM 450 may be formed on a surface of an outmost inorganic film of the encapsulation unit 410, cracks may be prevented from occurring in the inorganic film of the encapsulation unit 410, and the surface of the outmost inorganic film of the encapsulation unit 410 may be effectively protected.

The encapsulation unit 410 and the SAM 450 may be bonded to each other, and delamination phenomena of a surface of the encapsulation unit 410 may be reduced.

The end portion of the SAM 450 may control the surface energy of the SAM 450, and the adhesive properties between the SAM 450 and the adhesive layer 460, which may be formed on an upper surface of the SAM 450, may be improved.

The SAM 450 may reduce the delamination of the adhesive layer 460 from the surface of the encapsulation unit 410 and also reduce damage to the surface of the encapsulation unit 410 by the adhesive layer 460.

By using the above-described structure, the polarization layer 470 may be stably disposed on an upper portion of the adhesive layer 460. For example, the polarization layer 470 may be easily bonded to the adhesive layer 460 and may be prevented from being delaminated from the adhesive layer 460.

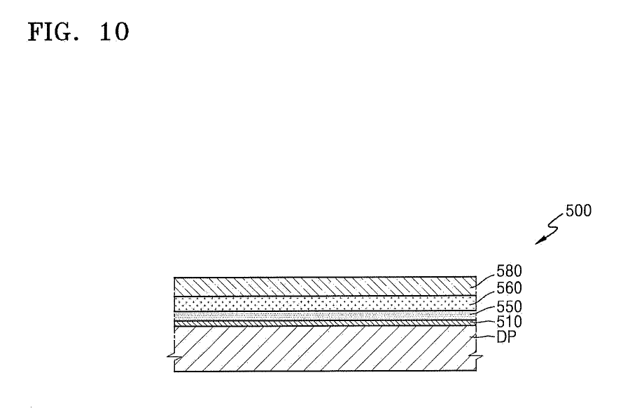

FIG. 10 illustrates a schematic cross-sectional view of a display apparatus 500 according to an exemplary embodiment.

Referring to FIG. 10, the display apparatus 500 according to the present embodiment may include a display unit DP, an encapsulation 510, an SAM 550, an adhesive layer 560, and a touch panel 580.

For convenience, different elements from the previously described embodiments will be explained.

The display unit DP may include a display element to realize at least a visible light beam. The display element may include various kinds of display elements. The display element may be the organic light-emitting device as described in the previously described embodiments. According to an exemplary embodiment, the display element may include a liquid crystal display element or other various kinds of display elements.

The encapsulation unit 510 may be formed on the display unit DP. The encapsulation unit 510 may protect the display unit SP and also protect the display element.

The encapsulation unit 510 may include at least an outmost inorganic film. The encapsulation unit 510 may selectively include a structure illustrated in FIG. 7A, FIG. 7B, or FIG. 7C, for example.

The SAM 550 may be formed on the encapsulation unit 510.

The SAM 550 may be substantially the same as the SAM 150, 250, 350, or 450, and detail descriptions thereof will be omitted.

The display unit DP according to the present embodiment may include a substrate as stated above.

The adhesive layer 560 may be formed above the SAM 550.

The adhesive layer 560 may be formed on the SAM 550 and may include various materials. For example, the adhesive layer 560 may include silicon.

The adhesive layer 560 including silicon may improve adhesive properties with the SAM 550, which may be formed by using silane.

According to an exemplary embodiment, the adhesive layer 560 may include a PSA.

The touch panel 580 may be formed on the adhesive layer 560. For example, the adhesive layer 560 may be disposed between the touch panel 580 and the SAM 550.

The touch panel 580 may include one or more touch patterns to detect a user touch when a user touches the touch panel 580. The touch pattern may include one or more of various types, such as a single layer or a multilayer.

By using the touch panel 580, the display apparatus 500 may realize a visible light beam and also improve user convenience through the detection of the user touch.

In the display apparatus 500 according to the present embodiment, the SAM 550 may effectively protect the encapsulation unit 510. For example, the SAM 550 may be formed on a surface of the outmost inorganic film of the encapsulation unit 510, cracks may be prevented from occurring in the inorganic film of the encapsulation unit 510, and the surface of the outmost inorganic film of the encapsulation unit 510 may be effectively protected.

The encapsulation unit 510 and the SAM 550 may be bonded to each other, and delamination phenomena of a surface of the encapsulation unit 510 may be reduced.

The end portion of the SAM 550 may control the surface energy of the SAM 550, and the adhesive properties between the SAM 550 and the adhesive layer 560, which may be formed on an upper surface of the SAM 550, may be improved.

The SAM 550 may reduce the delamination of the adhesive layer 560 from the surface of the encapsulation unit 510 and also reduce damage to the surface of the encapsulation unit 510 by the adhesive layer 560.

By using the above-described structure, the touch panel 580 may be stably disposed on an upper portion of the adhesive layer 560. For example, the touch panel 580 may be easily bonded to the adhesive layer 560 and may be prevented from being delaminated from the adhesive layer 560.

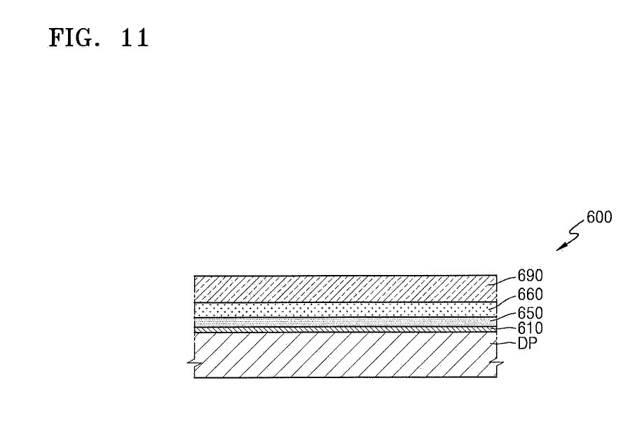

FIG. 11 illustrates a schematic cross-sectional view of a display apparatus 600 according to an exemplary embodiment.

Referring to FIG. 11, the display apparatus 600 according to the present embodiment may include a display unit DP, an encapsulation 610, an SAM 650, an adhesive layer 660, and a cover member 690.

For convenience, different elements from the previously described embodiments will be explained.

The display unit DP may include a display element to realize at least a visible light beam. The display element may include various kinds of display elements. The display element may be the organic light-emitting device as described in the previously described embodiments. According to an exemplary embodiment, the display element may include a liquid crystal display element or other various kinds of display elements.

The encapsulation unit 610 may be formed on the display unit DP. The encapsulation unit 610 may protect the display unit SP and also protect the display element.

The encapsulation unit 610 may include at least an outmost inorganic film. The encapsulation unit 610 may selectively include a structure illustrated in FIG. 7A, FIG. 7B, or FIG. 7C, for example.

The SAM 650 may be formed on the encapsulation unit 610.

The SAM 650 may be substantially the same as the SAM 150, 250, 350, 450, or 550, and detail descriptions thereof will be omitted.

The display unit DP according to the present embodiment may include a substrate as stated above.

The adhesive layer 660 may be formed above the SAM 650.

The adhesive layer 660 may be formed on the SAM 650 and may include various materials. For example, the adhesive layer 660 may include silicon.

The adhesive layer 660 including silicon may improve adhesive properties with the SAM 650, which may be formed by using silane.

According to an exemplary embodiment, the adhesive layer 660 may include a PSA.

The cover member 690 may be formed on the adhesive layer 660. For example, the adhesive layer 660 may be disposed between the cover member 690 and the SAM 650.

The cover member 690 may protect the display apparatus 600 during using the display apparatus 600. The cover member 690 may reduce or prevent breakage of the display unit DP from shocks applied to the display unit DP and may improve durability of the display unit DP. The cover member 690 may include various materials, for example, a glass material or a plastic material. According to an exemplary embodiment, when a light beam generated from the display unit DP transmits toward a user through the cover member 690, the cover member 690 may include a light transmitting material.

In the display apparatus 600 according to the present embodiment, the SAM 650 may effectively protect the encapsulation unit 610. For example, the SAM 650 may be formed on a surface of the outmost inorganic film of the encapsulation unit 610, cracks may be prevented from occurring in the inorganic film of the encapsulation unit 610, and the surface of the outmost inorganic film of the encapsulation unit 610 may be effectively protected.

The encapsulation unit 610 and the SAM 650 may be bonded to each other, and delamination phenomena of a surface of the encapsulation unit 610 may be reduced.

The end portion of the SAM 650 may control the surface energy of the SAM 650, and the adhesive properties between the SAM 650 and the adhesive layer 660, which may be formed on an upper surface of the SAM 650, may be improved.

The SAM 650 may reduce the delamination of the adhesive layer 660 from the surface of the encapsulation unit 610 and also reduce damage to the surface of the encapsulation unit 610 by the adhesive layer 660.

By using the above-described structure, the cover member 690 may be stably disposed on an upper portion of the adhesive layer 660. For example, the cover member 690 may be easily bonded to the adhesive layer 660 and may be prevented from being delaminated from the adhesive layer 660.

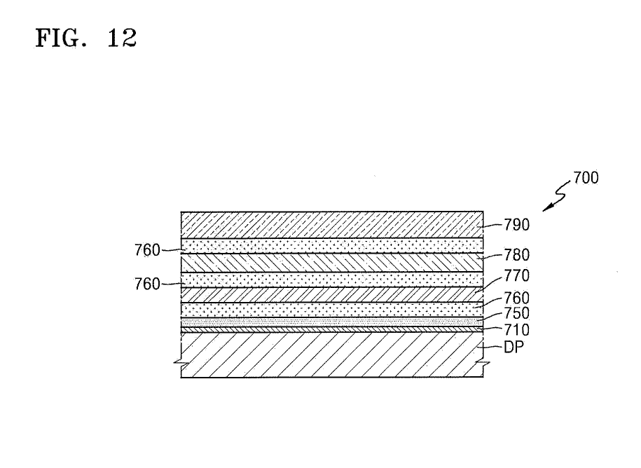

FIG. 12 illustrates a schematic cross-sectional view of a display apparatus 700 according to one exemplary embodiment.

Referring to FIG. 12, the display apparatus 700 according to the present embodiment may include a display unit DP, an encapsulation 710, an SAM 750, an adhesive layer 760, a polarization layer 770, a touch panel 780, and a cover member 790.

For convenience, different elements from the previously described embodiments will be explained.

The display unit DP may include a display element to realize at least a visible light beam. The display element may include various kinds of display elements. The display element may be the organic light-emitting device as described in the previously described embodiments. According to an exemplary embodiment, the display element may include a liquid crystal display element or other various kinds of display elements.

The encapsulation unit 710 may be formed on the display unit DP. The encapsulation unit 710 may protect the display unit SP and also protect the display element.

The encapsulation unit 710 may include at least an outmost inorganic film. The encapsulation unit 710 may selectively include a structure illustrated in FIG. 7A, FIG. 7B, or FIG. 7C, for example.

The SAM 750 may be formed on the encapsulation unit 710.

The SAM 750 may be substantially the same as the SAM 150, 250, 350, 450, 550, or 650, and detail descriptions thereof will be omitted.

The display unit DP according to the present embodiment may include a substrate as stated above.

The adhesive layer 760 may be formed above the SAM 750.

The adhesive layer 760 may be formed on the SAM 750 and may include various materials. For example, the adhesive layer 760 may include silicon.

The adhesive layer 760 including silicon may improve adhesive properties with the SAM 750, which may be formed by using silane.

According to an exemplary embodiment, the adhesive layer 760 may include a PSA.

The polarization layer 770 may be formed on the adhesive layer 760. For example, the adhesive layer 760 may be disposed between the polarization layer 770 and the SAM 750.

The touch panel 780 may be formed on the polarization layer 770. For example, the adhesive layer 760 may be disposed between the touch panel 780 and the polarization layer 770. According to an exemplary embodiment, the adhesive layer may be omitted between the touch panel 780 and the polarization layer 770.

The cover member 790 may be formed on the touch panel 780. For example, the adhesive layer 760 may be disposed between the touch panel 780 and the cover member. According to an exemplary embodiment, the adhesive layer may be omitted between the touch panel 780 and the cover member 790.

In the display apparatus 700 according to the present embodiment, the SAM 750 may effectively protect the encapsulation unit 710. For example, the SAM 750 may be formed on a surface of an outmost inorganic film of the encapsulation unit 710, cracks may be prevented from occurring in the inorganic film of the encapsulation unit 710, and the surface of the outmost inorganic film of the encapsulation unit 710 may be effectively protected.

The encapsulation unit 710 and the SAM 750 may be bonded to each other, and delamination phenomena of a surface of the encapsulation unit 710 may be reduced.

The end portion of the SAM 750 may control the surface energy of the SAM 750, and the adhesive properties between the SAM 750 and the adhesive layer 760, which may be formed on an upper surface of the SAM 750, may be improved.

The SAM 750 may reduce the delamination of the adhesive layer 760 from the surface of the encapsulation unit 710 and also reduce damage to the surface of the encapsulation unit 710 by the adhesive layer 760.

By using the above-described structure, the polarization layer 770 may be stably disposed on an upper portion of the adhesive layer 760, and sequentially, the touch panel 780 and the cover member 790 may be stably disposed over the adhesive layer 760. For example, the SAM 750 may effectively protect the surface of the encapsulation unit 710 in a case of a potential increase of stress applied to the surface of the encapsulation unit 710 when a plurality of members, such as the polarization layer 770, the touch panel 780, and the cover member 790, are disposed over the encapsulation unit 710.

By way of summation and review, a display apparatus may include an encapsulation unit to protect components of the display apparatus. During use or manufacture of the display apparatus, cracks may occur in the encapsulation unit, or the encapsulation unit may be damaged. When the display apparatus is manufactured or used, various members may be disposed above the encapsulation unit, and the display apparatus may have limitations to protect the encapsulation unit through the various members and attach the various members to the encapsulation unit.

One or more exemplary embodiments include a display apparatus having excellent durability and user convenience.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A display apparatus, comprising:
a display including a display element;
an encapsulation layer on the display, the encapsulation layer including an outmost inorganic film; and
a self-assembled monolayer on the encapsulation layer, self-assembled monolayer including a head portion, a chain portion connected to the head portion, and an end portion connected to the chain portion.

2. The display apparatus as claimed in claim 1, wherein the head portion of the self-assembled monolayer is connected to the outmost inorganic film of the encapsulation layer.

3. The display apparatus as claimed in claim 1, wherein the head portion of the self-assembled monolayer includes silicon.

4. The display apparatus as claimed in claim 1, wherein the head portion of the self-assembled monolayer is connected to the outmost inorganic film of the encapsulation layer through covalent bonds.

5. The display apparatus as claimed in claim 1, wherein the chain portion of the self-assembled monolayer includes an alkyl chain.

6. The display apparatus as claimed in claim 1, wherein the end portion of the self-assembled monolayer includes a hydroxyl group, a methyl group, an amino group, or a phosphate group.

7. The display apparatus as claimed in claim 1, wherein the encapsulation layer includes one or more organic films and one or more inorganic films between the outmost inorganic film and the display.

8. The display apparatus as claimed in claim 1, further comprising:
an adhesive layer on a first surface of the self-assembled monolayer opposite to a second surface of the self-assembled monolayer facing the encapsulation layer, among surfaces of the self-assembled monolayer.

9. The display apparatus as claimed in claim 8, wherein the adhesive layer includes silicon.

10. The display apparatus as claimed in claim 8, wherein the adhesive layer includes a pressure sensitive adhesive.

11. The display apparatus as claimed in claim 8, further comprising:
a polarization layer on a first surface of the adhesive layer opposite to a second surface of the adhesive layer facing the self-assembling monolayer, among surfaces of the adhesive layer.

12. The display apparatus as claimed in claim 8, further comprising:
a touch panel on a first surface of the adhesive layer opposite to a second surface of the adhesive layer facing the self-assembled monolayer, among surfaces of the adhesive layer, and detecting a user touch on the touch panel.

13. The display apparatus as claimed in claim 8, further comprising:
a cover member on a first surface of the adhesive layer opposite to a second surface of the adhesive layer facing the self-assembled monolayer, among surfaces of the adhesive layer.

14. The display apparatus as claimed in claim 8, further comprising:
a polarization layer, a touch panel, and a cover member sequentially on a first surface of the adhesive layer opposite to a second surface of the adhesive layer facing the self-assembled monolayer, among surfaces of the adhesive layer.

15. The display apparatus as claimed in claim 1, wherein:
the display element includes a first electrode, a second electrode, and an intermediate layer; and
the intermediate layer includes at least one organic light-emitting device, the intermediate layer being between the first electrode and the second electrode.
